(19) United States
(12) Patent Application Publication
(10) Pub. No.: US 2024/0200200 A1
(43) Pub. Date: Jun. 20, 2024

(54) STRETCH FILM HAVING METALIZED REFLECTIVE SURFACE PROVIDING HEAT INSULATION

(71) Applicant: Naci Tamer ÖZERDEN, Istanbul (TR)

(72) Inventor: Naci Tamer ÖZERDEN, Istanbul (TR)

(21) Appl. No.: 18/554,503

(22) PCT Filed: Apr. 6, 2022
(86) PCT No.: PCT/TR22/50303

§ 371 Date: Oct. 9, 2023

(30) Foreign Application Priority Data
Apr. 8, 2021 (TR) 2021/006314

(51) Int. Cl. C23C 30/00

(52) U.S. Cl. CPC C23C 30/00

(57) ABSTRACT

Disclosed is a metalized stretch film containing a polymer based film layer and having a metalized surface layer applied on at least one surface of the polymer based film layer.

### THE FIELD OF THE INVENTION

The invention relates to packaging products.

Invention particularly relates to stretch film having at least one metalized reflective surface providing heat insulation.

### BACKGROUND OF THE INVENTION

Heat insulation cannot be made by standard stretch films and thus prevention of short shelf lives of products quality damages cannot be achieved. Standard stretch films basically have such deficiency and this invention sustains original product temperature for longer periods and thus lengthens shelf life and enhance food safety and thus eliminates said deficiency.

For heat sensitive products, heat insulated package products are used to wrap around the pallet. In such cases use of stretch film together with heat insulated pallet cover is needed. Thus, more consumable materials are used and additional labor are needed.

Storing, unloading, loading, keeping and in-market operation processes for cold chain food products are all subject to temperature changes. In such cases various heat insulation covers are used. With the invention heat insulation feature will be provided for product during standard stretching process without need for any additional cost and handling costs.

Stretch film heavily used for food products shipment does not support maintaining original temperature of products at current status for longer time.

Lack of heat insulation feature of stretch film types contacting food in kitchen causes short life of product and loss of freshness. Alternatively aluminium foil use is needed due to lack of heat insulation feature of the stretch film types. Our invention provides heat insulation and thus provides longer use lives as well as freshness of products stretched by the product of our invention and therefore eliminates need for alternative product use.

This present invention also provides same benefits for heat sensitive products of chemistry and paint industries.

As a result, due to above-described disadvantages and inadequacies of existing solutions it has been necessary to make development in the related art.

### BRIEF DESCRIPTION OF THE INVENTION

The present invention relates to metalized stretch film meeting the needs mentioned above, eliminating all disadvantages and providing some additional advantages.

Primary purpose of the invention is to disclose stretch film having at least one metalized reflective surface providing heat insulation. This invention will be used for packaging products sensitive to heat in a manner to function as stretch film having one or both sides metalized reflective surface and providing heat insulation. The invention also provides heat insulation feature for packaging applications using stretch films.

Another purpose of the invention is to disclose a stretch film providing heat insulation convenient for use in any fields where standard stretch film can be applied. Since the invention is formed by covering a reflective surface onto standard stretch film, it not only prevents damage to package where standard stretch film is applicable but also provides maintaining ideal temperature range of product for longer time period and thus eliminates need for additional insulation material use.

A further purpose of the invention is to provide a stretch film capable of protecting temperature of household or industrial food products in cold or hot areas for longer time periods and to enhance shelf lives thereof during shipment and thus improve food safety. Thus, it is aimed to eliminate use of additional materials needed for heat insulation during storing and shipment of food products.

The structural and characteristic features of the invention and all advantages will be understood better in figures and detailed descriptions given below and therefore, the assessment should be made taking into account of these detailed explanations.

### BRIEF DESCRIPTION OF FIGURES

FIG. 1 is schematic cross-sectional view of stretch film in the related art.

FIG. 2 is schematic cross-sectional view of embodiment of the invention.

FIG. 3 is another schematic cross-sectional view of embodiment of the invention.

### DESCRIPTION OF REFERENCES

1. Metalized stretch film
10 Polymer based film layer
20 Metalized surface layer

### DETAILED DESCRIPTION OF THE INVENTION

In this detailed description, the metalized stretch film coating of the invention have been described in a manner without any restriction and only for purpose of better understanding of the matter.

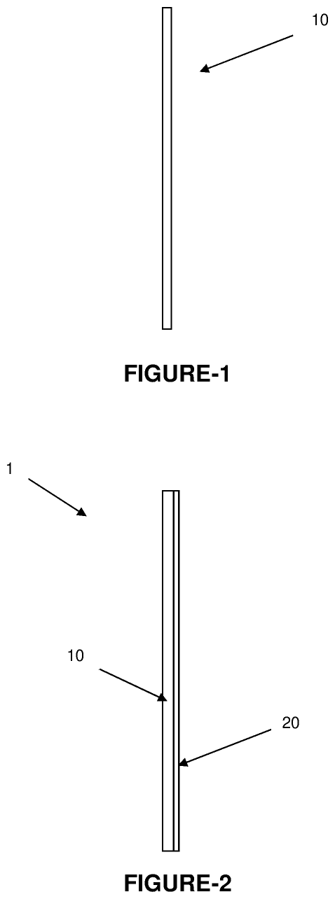

The invention relates to a composite structured metalized stretch film (1) displaying insulation feature as a result of metallization process applied by means of applying metal steam onto single or both surface/s of a stretch film of the related art shown in FIG. 1.

The invention is a metalized stretch film (1) containing polymer based film layer (10) and comprises metalized surface layer (20) applied on at least one surface of said polymer based film layer (10) as shown in FIG. 2.

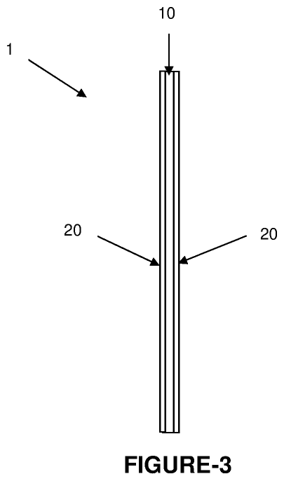

One alternative embodiment of the invention comprises metalized surface layer (20) applied on both surfaces of said polymer based film layer (10) as shown in FIG. 3.

The said polymer based film layer (10) is made from a polymer and preferably is polyethylene based.

The said metalized surface layer (20) is obtained as a result of applying metal steam, preferably aluminium steam, onto a polymer based film layer (10).

Another embodiment of the invention is a heat insulated stretch film which functions as standard stretch film in packaging products as well as functions as heat insulated pallet cover because of having metalized reflective surface and thus protects products against external climate conditions.

With providing reflective surface by subjecting standard stretch film to metallization process, it not only prevents pallet loads becoming loose in area where standard stretch film can be applied but also provides longer protection of original temperatures of the products and thus eliminates the need of using additional insulation material.

1. A metalized stretch film a polymer based film layer and comprising a metalized surface layer applied on at least one surface of said polymer based film layer.

2. The metalized stretch film according to claim 1, wherein the metalized surface layer is applied on both surfaces of said polymer based film layer.

3. The metalized stretch film according to claim 1, wherein the said polymer based film layer is polyethylene based.

4. The metalized stretch film according to claim 1, wherein the said metalized surface layer is aluminum based.
